(19) United States
(12) Patent Application Publication
(10) Pub. No.: US 2025/0193811 A1
(43) Pub. Date: Jun. 12, 2025

(54) CONTROL OF SATURATED OUTPUT POWER OF A POWER AMPLIFIER FOR SIMULTANEOUS TRANSMIT AND RECEIVE OPERATION

(71) Applicant: Skyworks Solutions, Inc., Irvine, CA (US)

(72) Inventors: Grant Darcy Poulin, Carp (CA); Wesley John Boyd, Coal Valley, IL (US); Hichem Ben Hedi Abdallah, Andover, MA (US); Jose Mari Elizalde Harrison, Newburyport, MA (US)

(21) Appl. No.: 18/952,559

(22) Filed: Nov. 19, 2024

Related U.S. Application Data
(60) Provisional application No. 63/608,490, filed on Dec. 11, 2023.

(51) Int. Cl. H04W 52/52; H03F 3/24; H04W 84/12; H04W 88/08

(52) U.S. Cl. CPC H04W 52/52; H03F 3/245; H03F 2200/294; H03F 2200/451; H04W 84/12; H04W 88/08

(57) ABSTRACT

Power amplifiers with saturated output power (Psat) control for simultaneous transmit and receive (STR) are disclosed. In certain embodiments, a front-end system includes a low noise amplifier for amplifying a receive signal and a power amplifier for amplifying a transmit signal. The power amplifier receives a control signal for adjusting Psat from a STR control circuit, which can be part of a Wi-Fi system controller. During normal operation, the control signal sets the power amplifier to operate with a first or nominal Psat level. However, during one or more STR operating scenarios, the control signal is used to increase the power amplifier's PSAT from the nominal Psat level to a second or increased Psat level in which the power amplifier operates with reduced out-of-band noise and heightened linearity.

### CROSS-REFERENCE TO RELATED APPLICATIONS

This application claims the benefit of priority under 35 U.S.C. § 119 of U.S. Provisional Patent Application No. 63/608,490, filed Dec. 11, 2023 and titled “CONTROL OF SATURATED OUTPUT POWER OF A POWER AMPLIFIER FOR SIMULTANEOUS TRANSMIT AND RECEIVE OPERATION,” which is herein incorporated by reference in its entirety.

### BACKGROUND

### Field

Embodiments of the invention relate to electronic systems, and in particular, to radio frequency (RF) electronics.

### Description of the Related Technology

Power amplifiers are used in RF communication systems to amplify RF signals for transmission via antennas.

Examples of RF communication systems with one or more power amplifiers include, but are not limited to, mobile phones, tablets, base stations, access points, customer-premises equipment (CPE), laptops, and wearable electronics. For example, in wireless devices that communicate using a cellular standard, a wireless local area network (WLAN) standard (such as an 802.11 standard for Wi-Fi), and/or any other suitable communication standard, a power amplifier can be used for RF signal amplification. An RF signal can have a frequency in the range of about 30 kilohertz (kHz) to 300 gigahertz (GHz).

### SUMMARY

In certain embodiments, an access point for a Wi-Fi network is disclosed. The access point includes a front-end system including a low noise amplifier configured to amplify a receive signal of a first frequency band, and a power amplifier configured to amplify a transmit signal of a second frequency band, the power amplifier further configured to receive a control signal that controls a saturated output power of the power amplifier. The access point further includes a system controller including a control circuit configured to use the control signal to operate the power amplifier with a first saturated output power level in a nominal operating mode, and to use the control signal to operate the power amplifier with a second saturated output power level greater than the first saturated output power level in one or more operating modes associated with simultaneous transmission of the transmit signal and reception of the receive signal.

In some embodiments, the control circuit further detects the one or more operating modes based on comparing a power of the transmit signal to a power threshold.

In various embodiments, the control circuit further detects the one or more operating modes based on comparing a channel bandwidth of at least one of the transmit signal or the receive signal to a bandwidth threshold.

In several embodiments, the control circuit further controls a channel selection of at least one of the receive signal or the transmit signal in the one or more operating modes.

In some embodiments, the control circuit further controls a channel bandwidth of at least one of the receive signal or the transmit signal in the one or more operating modes.

In various embodiments, the control circuit further controls an output power of the transmit signal in the one or more operating modes.

In several embodiments, the front-end system further includes an output power limiter connected to an output of the power amplifier. According to a number of embodiments, the front-end system further includes an acoustic wave filter downstream from the output of the power amplifier and protected by the output power limiter.

In some embodiments, the first frequency band is a Wi-Fi 5 GHz band and the second frequency band is a Wi-Fi 6 GHz band.

In various embodiments, the first frequency band is a Wi-Fi 6 GHz band and the second frequency band is a Wi-Fi 5 GHz band.

In some embodiments, the front-end system further includes a controllable load impedance connected to an output of the power amplifier, the control signal operable to control the saturated output power of the power amplifier by adjusting the controllable load impedance.

In various embodiments, the front-end system further includes a controllable bias circuit configured to bias the power amplifier, the control signal operable to control the saturated output power of the power amplifier by adjusting a bias provided by the controllable bias circuit.

In several embodiments, the front-end system further includes a controllable supply voltage circuit configured to generate a power amplifier supply voltage for the power amplifier, the control signal operable to control the saturated output power of the power amplifier by adjusting a voltage level of the power amplifier supply voltage provided by the controllable supply voltage circuit.

In certain embodiments, the present disclosure relates to a radio frequency communication system. The radio frequency communication system includes a low noise amplifier configured to amplify a receive signal of a first frequency band, a power amplifier configured to amplify a transmit signal of a second frequency band, and to receive a control signal that controls a saturated output power of the power amplifier, and a control circuit configured to use the control signal to operate the power amplifier with a first saturated output power level in a nominal operating mode, and to use the control signal to operate the power amplifier with a second saturated output power level greater than the first saturated output power level in one or more operating modes associated with simultaneous transmission of the transmit signal and reception of the receive signal.

In various embodiments, the control circuit further detects the one or more operating modes based on comparing a power of the transmit signal to a power threshold.

In several embodiments, the control circuit further detects the one or more operating modes based on comparing a channel bandwidth of at least one of the transmit signal or the receive signal to a bandwidth threshold.

In some embodiments, the control circuit further controls a channel selection of at least one of the receive signal or the transmit signal in the one or more operating modes.

In various embodiments, the control circuit further controls a channel bandwidth of at least one of the receive signal or the transmit signal in the one or more operating modes.

In several embodiments, the control circuit further controls an output power of the transmit signal in the one or more operating modes.

In some embodiments, the radio frequency communication system further includes an output power limiter connected to an output of the power amplifier. In a number of embodiments, the radio frequency communication system further includes an acoustic wave filter downstream from the output of the power amplifier and protected by the output power limiter.

In various embodiments, the first frequency band is a Wi-Fi 5 GHz band and the second frequency band is a W-Fi 6 GHz band.

In several embodiments, the first frequency band is a Wi-Fi 6 GHz band and the second frequency band is a W-Fi 5 GHz band.

In some embodiments, the radio frequency communication system further includes a controllable load impedance connected to an output of the power amplifier, the control signal operable to control the saturated output power of the power amplifier by adjusting the controllable load impedance.

In various embodiments, the radio frequency communication system further includes a controllable bias circuit configured to bias the power amplifier, the control signal operable to control the saturated output power of the power amplifier by adjusting a bias provided by the controllable bias circuit.

In several embodiments, the radio frequency communication system further includes a controllable supply voltage circuit configured to generate a power amplifier supply voltage for the power amplifier, the control signal operable to control the saturated output power of the power amplifier by adjusting a voltage level of the power amplifier supply voltage provided by the controllable supply voltage circuit.

In certain embodiments, a method of radio frequency signal communication is disclosed. The method includes amplifying a receive signal of a first frequency band using a low noise amplifier and amplifying a transmit signal of a second frequency band using a power amplifier, the power amplifier receiving a control signal that controls a saturated output power of the power amplifier. The method further includes operating the power amplifier with a first saturated output power level in a nominal operating mode using the control signal, and operating the power amplifier with a second saturated output power level greater than the first saturated output power level in one or more operating modes associated with simultaneous transmission of the transmit signal and reception of the receive signal using the control signal.

In some embodiments, the method further includes detecting the one or more operating modes based on comparing a power of the transmit signal to a power threshold.

In several embodiments, the method further includes detecting the one or more operating modes based on comparing a channel bandwidth of at least one of the transmit signal or the receive signal to a bandwidth threshold.

In various embodiments, the method further includes controlling a channel selection of at least one of the receive signal or the transmit signal in the one or more operating modes.

In several embodiments, the method further includes controlling a channel bandwidth of at least one of the receive signal or the transmit signal in the one or more operating modes.

In some embodiments, the method further includes controlling an output power of the transmit signal in the one or more operating modes.

In various embodiments, the method further includes limiting an output power at an output of the power amplifier using an output power limiter. According to a number of embodiments, the method further includes protecting an acoustic wave filter downstream from the output of the power amplifier using the output power limiter.

In several embodiments, the first frequency band is a Wi-Fi 5 GHz band and the second frequency band is a W-Fi 6 GHz band.

In various embodiments, the first frequency band is a Wi-Fi 6 GHz band and the second frequency band is a W-Fi 5 GHz band.

In some embodiments, the method further includes controlling the saturated output power of the power amplifier by adjusting a controllable load impedance at an output of the power amplifier using the control signal.

In several embodiments, the method further includes controlling the saturated output power of the power amplifier by adjusting a bias provided by a controllable bias circuit to the power amplifier.

In various embodiments, the method further includes controlling the saturated output power of the power amplifier by adjusting a voltage level of a power amplifier supply voltage of the power amplifier.

### BRIEF DESCRIPTION OF THE DRAWINGS

Embodiments of this disclosure will now be described, by way of non-limiting example, with reference to the accompanying drawings.

FIG. 1 is a schematic diagram of one embodiment of a Wi-Fi network.

FIG. 2 is a schematic diagram of one example of frequency separation between Wi-Fi 5 GHz and Wi-Fi 6 GHz frequency bands.

FIG. 3A is a schematic diagram of one example of self-interference for a Wi-Fi access point simultaneously transmitting on a Wi-Fi 6 GHz frequency band and receiving on a Wi-Fi 5 GHz frequency band.

FIG. 3B is a schematic diagram of one example of self-interference for a Wi-Fi access point simultaneously receiving on a Wi-Fi 6 GHz frequency band and transmitting on a Wi-Fi 5 GHz frequency band.

FIG. 4A is a graph of one example of out of band (OOB) noise versus backoff from saturated output power (Psat).

FIG. 4B is a graph of one example of OOB noise versus channel offset from band edge.

FIG. 5A is a schematic diagram of a Wi-Fi communication system according to one embodiment.

FIG. 5B is a schematic diagram of a Wi-Fi communication system according to another embodiment.

FIG. 6A is a schematic diagram of a power amplifier with Psat control according to one embodiment.

FIG. 6B is a schematic diagram of a power amplifier with Psat control according to another embodiment.

FIG. 6C is a schematic diagram of a power amplifier with Psat control according to another embodiment.

FIG. 7A is a schematic diagram of one embodiment of a packaged module.

FIG. 7B is a schematic diagram of a cross-section of the packaged module of FIG. 7A taken along the lines 7B-7B.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

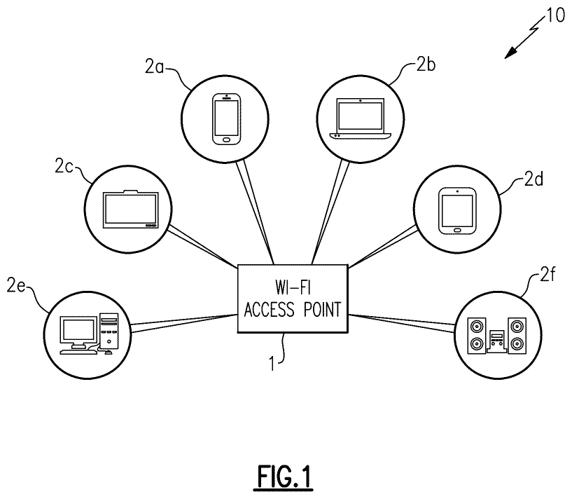

FIG. 1 is a schematic diagram of one embodiment of a Wi-Fi network 10.

The Wi-Fi network 10 includes a Wi-Fi access point 1 and various examples of Wi-Fi enabled equipment, including a mobile phone 2a, a laptop 2b, a smart television 2c, a tablet 2d, a desktop computer 2e, and a smart audio system 2f.

Although specific examples of Wi-Fi enabled equipment are illustrated in FIG. 1, a Wi-Fi network can include Wi-Fi enabled equipment of other numbers and/or types. Thus, although various examples of Wi-Fi enabled equipment are shown, the teachings herein are applicable to a wide variety of types of equipment, including, but not limited to, mobile phones, tablets, laptops, IoT devices, wearable electronics, customer premises equipment (CPE), wireless-connected vehicles, wireless relays, and/or a wide variety of other communication devices. Furthermore, although one Wi-Fi access point is depicted, multiple Wi-Fi access points can be included in a Wi-Fi network.

The illustrated Wi-Fi network 10 of FIG. 1 supports communication over Wi-Fi 7 (802.11be) as well as to subsequent Wi-Fi technologies such as Wi-Fi 8 and beyond.

Wi-Fi 7, also referred to as IEEE 802.11be or Extremely High Throughput (EHT) Wi-Fi, is an amendment of the IEEE 802.11 standard adopted for 2024. Wi-Fi 7 is built upon 802.11ax and focuses on WLAN indoor and outdoor operation with stationary and pedestrian speeds. Wi-Fi 7 supports several frequency bands, including Wi-Fi 2.4 GHz, Wi-Fi 5 GHz, and Wi-Fi 6 GHz.

The Wi-Fi 5 GHz frequency band spans from 5170 megahertz (MHz) to 5895 MHz and corresponds to Unlicensed National Information Infrastructure (UNII) frequency ranges 1, 2A, 2B, 2C, 3, and 4. Additionally, the Wi-Fi 6 GHz frequency band spans from 5945 MHz to 7125 MHz and corresponds to UNII frequency ranges 5, 6, 7, and 8. The UNII-4 frequency range operates from 5850 MHz to 5895 MHz, and was designated in 2021 by the Federal Communications Commission (FCC) for use as additional Wi-Fi spectrum in the US.

Various communication links of the Wi-Fi network 10 have been depicted in FIG. 1. The communication links can be duplexed in a wide variety of ways, including, for example, using time-division duplexing (TDD). TDD is a type of radio frequency communications that uses about the same frequency for transmitting and receiving signals, and in which transmit and receive communications are switched in time. TDD can provide efficient use of spectrum and variable allocation of throughput between transmit and receive directions.

Advanced feature support for Wi-Fi 7 and beyond specifies Wi-Fi access points (and in certain instances, Wi-Fi enabled equipment) to support simultaneous transmit and receive (STR) over two different Wi-Fi frequency bands.

Thus, as part of the Wi-Fi 7 standard (and future versions), all access points must support STR operation in at least two frequency bands. One desirable STR split is to use the Wi-Fi 5 GHz band (UNII-1 to UNII-4) for the first band and the Wi-Fi 6 GHz band (UNII-5 to UNII-8) as the second band.

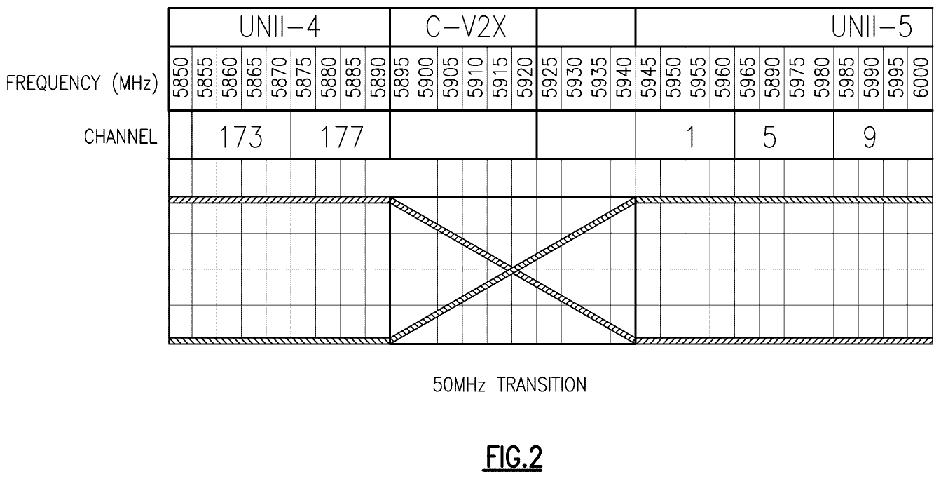

FIG. 2 is a schematic diagram of one example of frequency separation between Wi-Fi 5 GHz and Wi-Fi 6 GHz frequency bands. As depicted in FIG. 2A, only a 50 MHz frequency spacing is present between the upper edge of the Wi-Fi 5 GHz frequency band (upper edge of UNII-4) and the bottom edge of the Wi-Fi 6 GHz frequency band (lower edge of UNII-5).

In view of the small 50 MHz frequency spacing, self-interference between the Wi-Fi 5 GHz band and the Wi-Fi 6 GHz band is a significant problem when these bands are used for STR operation.

For example, self-interference can arise from transmit noise from a Wi-Fi transmitter falling into the receive band of a co-located Wi-Fi receiver, resulting in a reduction of range and throughput.

To support STR operation, stringent filtering is desired for both the Wi-Fi 5 GHz band and the Wi-Fi 6 GHz band.

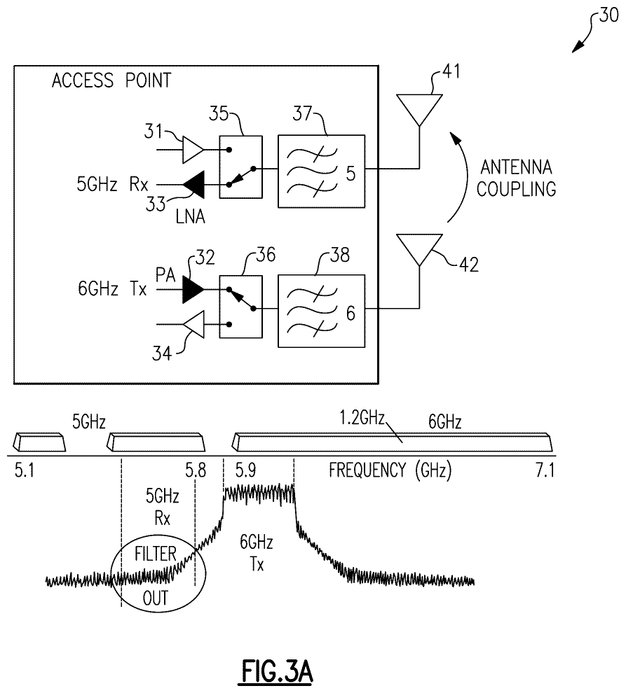

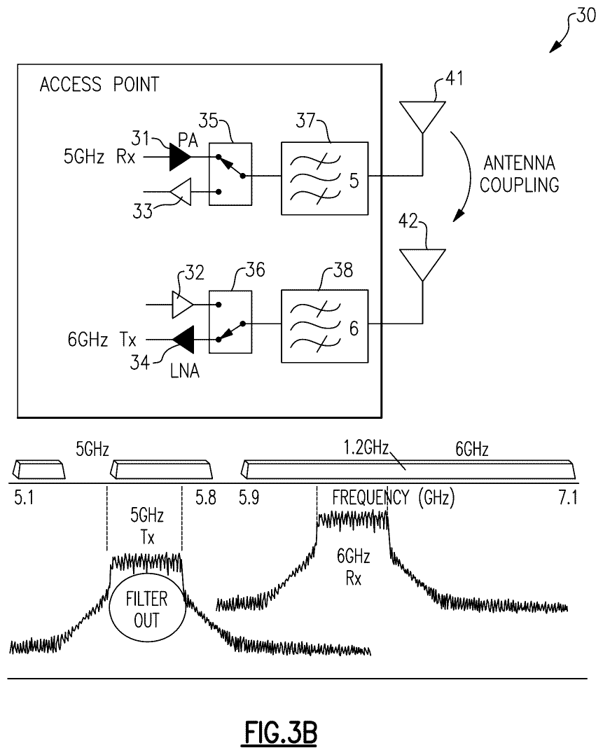

FIG. 3A is a schematic diagram of one example of self-interference for a Wi-Fi access point 30 simultaneously transmitting on a Wi-Fi 6 GHz frequency band and receiving on a Wi-Fi 5 GHz frequency band. FIG. 3B is a schematic diagram of one example of self-interference for the Wi-Fi access point 30 simultaneously receiving on a Wi-Fi 6 GHZ frequency band and transmitting on a Wi-Fi 5 GHz frequency band.

With reference to FIGS. 3A and 3B, the Wi-Fi access point 30 includes a 5 GHz power amplifier (PA) 31, a 6 GHz power amplifier 32, a 5 GHz low noise amplifier (LNA) 33, a 6 GHz LNA 34, a 5 GHz transmit/receive (T/R) switch 35, a 6 GHz T/R switch 36, a 5 GHz band filter 37, a 6 GHz band filter 38, a 5 GHz antenna 41, and a 6 GHz antenna 42.

The 5 GHz band filter 37 reduces out of band (OOB) noise that would fall in the 6 GHz receive band, causing de-sensitization, and filters out the 6 GHz transmit signal that can degrade the linearity of the 5 GHz LNA 33.

In the example of FIG. 3A, the 6 GHz power amplifier 32 is transmitting while the 5 GHz LNA 33 is simultaneously receiving as part of STR operation for Wi-Fi 7. The 6 GHz band filter 38 is depicted as rejecting OOB noise from the 6 GHz transmit signal that degrades the noise floor and causes desensitization of the 5 GHz LNA 33.

The 6 GHz band filter 38 reduces OOB noise that would fall in the 5 GHZ receive band, causing desensitization, and filters out the 5 GHz transmit signal that can degrade the linearity of the 6 GHz LNA 34.

In the example of FIG. 3B, the 5 GHz power amplifier 31 is transmitting while the 6 GHz LNA 34 is simultaneously receiving as part of STR operation for Wi-Fi 7. The 6 GHz band filter 38 is depicted as rejecting 5 GHz transmit signal leakage that can otherwise saturate the 6 GHz LNA 34 and result in desensitization.

Thus, it is highly desirable to have a pair of filters than can operate to allow simultaneous UNII-4/UNII-5 operation for STR. However, such filters are extremely challenging to fabricate given the 50 MHz band separation between the upper edge of UNII-4 and the lower edge of UNII-5.

For example, in one application, the 5 GHz band filter 37 is specified to pass a signal at 5895 MHz with less than 2 decibels (2 dB) of insertion loss while providing rejection of more than 70 dB at 5945 MHz, which is only 50 MHz away. In another application, the 6 GHZ band filter 38 is specified to pass a signal at 5945 MHz with less than 2 dB of insertion loss while providing rejection of more than 70 dB at 5895 MHz, which is only 50 MHz away.

Achieving greater than 70 dB of rejection with only a 50 MHz transition band over process and temperature may be infeasible for existing filter technology, such as surface acoustic wave (SAW) filters and/or bulk acoustic wave (BAW) filters.

Provided herein are RF communication systems in which a saturated output power (Psat) of a power amplifier is controlled for STR operation. In certain embodiments, a front-end system includes a low noise amplifier for amplifying a receive signal and a power amplifier for amplifying a transmit signal. The power amplifier receives a control signal for adjusting Psat from a STR control circuit, which can be part of a Wi-Fi system controller. During normal operation, the control signal sets the power amplifier to operate with a first or nominal Psat level. However, during one or more STR operating scenarios, the control signal is used to increase the power amplifier's PSAT from the nominal Psat level to a second or increased Psat level in which the power amplifier operates with reduced OOB noise and heightened linearity.

By adjusting the power amplifier's Psat in this manner, OOB noise can be selectively reduced to meet difficult STR operating scenarios. Such channeling STR operating scenarios can be associated with STR on Wi-Fi 5 GHz and Wi-Fi 6 GHz bands for certain channel bandwidths and/or signal powers.

In certain implementations, the STR control circuit can also control at least one of channel selection, channel bandwidth, or output power to further aid in achieving sufficiently low OOB noise.

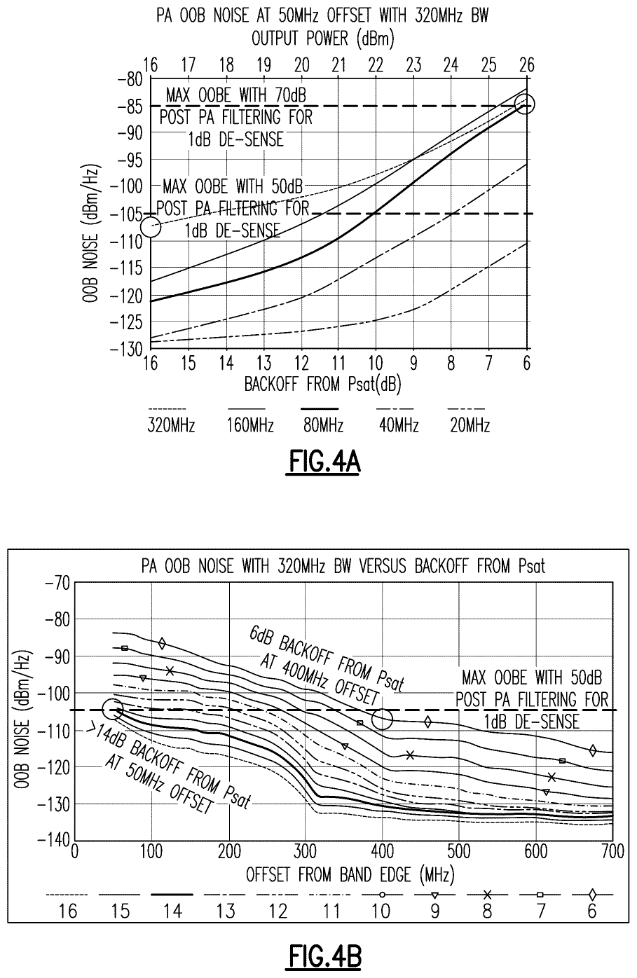

FIG. 4A is a graph of one example of OOB noise versus backoff from Psat.

The graph depicts measured power amplifier OOB noise at 50 MHz offset from the band edge for a 6 GHz PA, plotted as a function of backoff from the power amplifier's Psat. When operating at 320 MHz bandwidth and 6 dB backed off from Psat, the power amplifier's OOB noise is ˜−85 dBm/Hz.

For a case of Wi-Fi 7 using 4 transmit streams (for instance, for 4×4 multi-input multiple-output) and 25 dB of antenna isolation between the 5 GHz and 6 GHz antennas, the maximum allowed noise at the output of the 6 GHz power amplifier (after the output of the 6 GHz band filter) in the 5 GHz band is about −155 dBm/Hz.

Since the power amplifier's OOB noise is at −85 dBm, about 70 dB of filtering is needed in order to reduce the OOB noise at −85 dBm/Hz to the specified level of −155 dBm/Hz. However, achieving 70 dB filter rejection at 50 MHz offset is extremely challenging for a BAW or other filter design.

However, the inventors of the present disclosure have recognized that OOB emissions (OOBE) are reduced significantly as the power amplifier is operated at lower powers (for instance, the backoff from Psat is increased). For example, if the power amplifier is operated 16 dB backed off from Psat, OOBE will be reduced from −85 dBm/Hz to about −107 dBm/Hz, which is more than 20 dB. The reduction in OOBE achieved from adjusting Psat relaxes the filtering requirements. Furthermore, such benefits are achieved at any power and at any offset. It is possible to reduce OOB noise by operating the power amplifier at lower output powers, maintaining Psat. However, this will reduce the transmit range of the power amplifier, and as a result it will have a negative impact on overall Wi-Fi network performance. OOB emissions can also be reduced by maintaining the same transmit power, and by increasing Psat of the power amplifier.

Thus, in accordance with the teachings herein, a control signal is used to selectively increase a power amplifier's Psat for certain STR operating scenarios. For example, Psat be selectively increased for difficult STR scenarios when simultaneously transmitting in the Wi-Fi 5 GHz and Wi-Fi 6 GHz frequency bands.

Such difficult STR scenarios can be based on a power threshold (for example, transmit power greater than a threshold) and/or high channel bandwidths (for example, channel bandwidths greater than a threshold such as 40 MHz or higher). Thus, the power amplifier's Psat is selectively increased to relax filtering requirements for one or more difficult STR scenarios associated with very high filter rejection.

FIG. 4B is a graph of one example of OOB noise versus channel offset from band edge.

The graph depicts shows the OOB noise at various backoffs from Psat as a function of offset from the band edge of the transmit signal for a 320 MHz channel bandwidth.

As shown in FIG. 4B, OOBE is reduced by moving the channels apart from each other. Thus, when the operating channels are selected so that there is additional separation between the 6 GHz transmit channel and the 5 GHz receive channel (or between the 6 GHz receive channel and the 5 GHz transmit channel), power amplifier OOB noise decreases.

In one example with 50 dB of available BAW filtering, 14 dB backoff from Psat is needed to operate with 50 MHz of channel separation. However, only 6 dB backoff from Psat is needed to operate when the channel separation is increased from 50 MHz to 400 MHz.

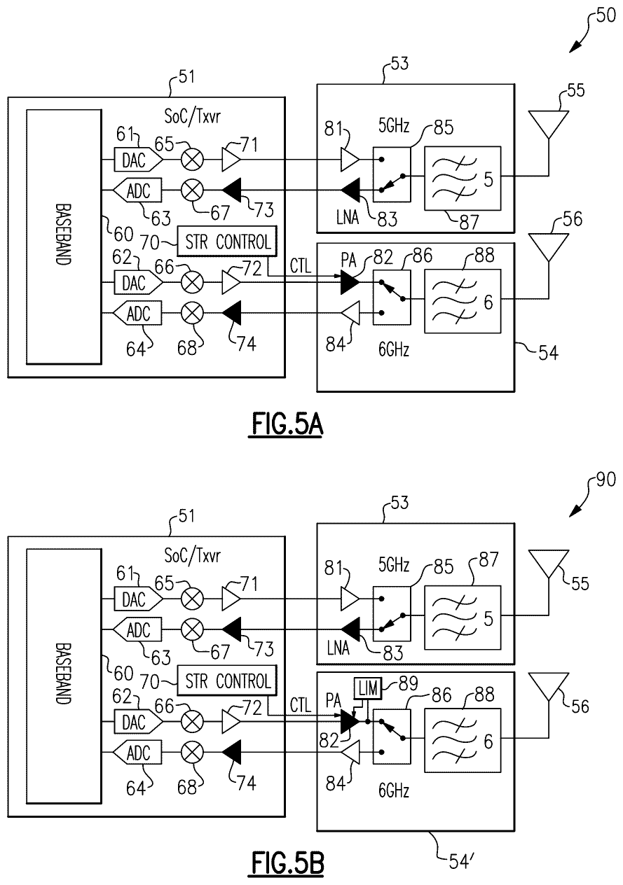

FIG. 5A is a schematic diagram of a Wi-Fi communication system 50 according to one embodiment. The Wi-Fi communication system 50 includes a transceiver 51 (for instance, a Wi-Fi system controller or SoC), a 5 GHz front-end system 53, a 6 GHz front-end system 54, a 5 GHz antenna 55, and a 6 GHz antenna 56. The Wi-Fi communication system 50 represents a Wi-Fi enabled system that operates with STR, such as a Wi-Fi access point or Wi-Fi enabled device.

In the illustrated embodiment, the transceiver 51 includes a baseband circuit 60, a 5 GHz transmit-path digital-to-analog converter (DAC) 61, a 6 GHz transmit-path DAC 62, a 5 GHz receive-path analog-to-digital converter (ADC) 63, a 6 GHz receive-path ADC 64, a 5 GHz transmit-path mixer 65, a 6 GHz transmit-path mixer 66, a 5 GHz receive-path mixer 67, a 6 GHz receive-path mixer 68, an STR control circuit 70, a 5 GHz transmit amplifier 71, a 6 GHz transmit amplifier 72, a 5 GHz receive amplifier 73, and a 6 GHz receive amplifier 74.

With continuing reference to FIG. 5A, the 5 GHz front-end system 53 includes a 5 GHz power amplifier 81, a 5 GHz LNA 83, a 5 GHz T/R switch 85, and a 5 GHz band filter 87 (for instance, a BAW filter). Additionally, the 6 GHz front-end system 54 includes a 6 GHz power amplifier 82, a 6 GHz LNA 84, a 6 GHz T/R switch 86, and a 6 GHz band filter 88 (for instance, a BAW filter).

As shown in FIG. 5A, the 6 GHz power amplifier 82 receives a control signal CTL from STR control circuit 70 of the transceiver 51 (for instance, Wi-Fi system controller) to determine where to set Psat. In response to detecting an STR operating mode in which improved OOBE is desired, the STR control circuit 70 uses the control signal CTL to selectively increase the power amplifier's Psat.

In FIG. 5A, an STR operating scenario in which 6 GHz is transmitting and 5 GHz is receiving is depicted. For this configuration of transmit and receive, the STR control circuit 70 uses the control signal CTL to selectively increase the Psat of the 6 GHz power amplifier 82. In certain implementations, Psat is selectively increased based on at least one of signal power being above a power threshold or channel bandwidth being above a bandwidth threshold.

Although not shown in FIG. 5A, a similar control signal can be provided from the STR control circuit 70 to the 5 GHz power amplifier 81 to selectively increase the Psat of the 5 GHz power amplifier 81 for certain operating scenarios in which 5 GHz is transmitting and 6 GHz is receiving.

In one embodiment, the depicted power amplifiers are designed to operate with Psat=32 dBm in nominal conditions (i.e., with the power amplifier's load impedance or the supply voltage set to achieve 32 dBm Psat). Additionally, a transmitting power amplifier will operate in nominal condition whenever transmit power, channel selection, and/or channel bandwidths are selected so that we can meet a de-sense target (for instance, 1 dB) with the power amplifier under nominal conditions. However, when the output power, channel bandwidth, and/or channel separation results in the power amplifier's OOB noise increasing to unacceptable levels, the transceiver 51 instructs the transmitting power amplifier (for instance, the 5 GHz power amplifier 81 or 6 GHz power amplifier 82 depending on mode) to enter a high linearity mode, reducing the power amplifier's OOB emissions by a certain amount (for instance, ˜20 dB). This will allow the system 50 to continue to operate to meet the de-sense target without reducing the transmit range.

FIG. 5B is a schematic diagram of a Wi-Fi communication system 90 according to another embodiment. The Wi-Fi communication system 90 includes a transceiver 51, a 5 GHz front-end system 53, a 6 GHz front-end system 54′, a 5 GHz antenna 55, and a 6 GHz antenna 56.

The Wi-Fi communication system 90 of FIG. 5B is similar to the Wi-Fi communication system 50 of FIG. 5A, except that the 6 GHz front-end system 54′ in FIG. 5B further includes an output power limiter 89 at the output of the 6 GHz power amplifier 82. The output power amplifier 89 can limit power in any suitable manner, including using feedback to the power amplifier 82 as shown in FIG. 5B.

The output power limiter 89 aids in protecting downstream components (for instance, switches, BAW filters, etc.) and/or the power amplifier itself in response to the Psat of the 6 GHz power amplifier 82 being increased.

For example, when a power amplifier's Psat is increased, the power amplifier is capable of delivering more transmit power. For instance, if a power amplifier's supply voltage is increased from 5V to 8V while keeping the load impedance constant, Psat will increase by approximately 4 dB, from ˜32 dBm to ˜36 dBm. This in turn means that the power amplifier would be capable of delivering 4 dB more power at mask limited power (increasing from ˜27 dBm to ˜31 dBm).

Absent a protection mechanism, operating a power amplifier at such a high output power would likely damage the power amplifier since the power amplifier's thermal and electrical characteristics are unlikely to support operation at such high output power.

Accordingly, an output power limiter can be included to provide a safeguard in place to limit maximum output power to a level within operational design tolerance at nominal supply voltage.

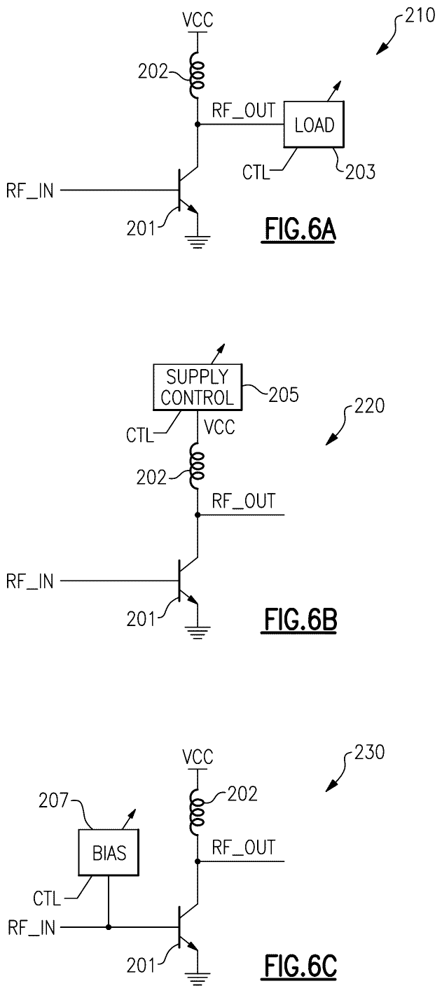

With general reference to FIGS. 6A to 6C, a power amplifier's Psat can be changed in any suitable way. For example, a power amplifier's Psat can be approximated by V²/2R_{L}, where V is the power amplifier's supply voltage and RI, is the power amplifier's load impedance. In one example, a power amplifier's Psat can be increased by reducing the power amplifier's load impedance, for instance, by load line switching to a different output matching network. In another example, selectively enabled transistors are added to the power amplifier's final driver stage, with switches and/or biasing used to enable the transistors when desired. When adding transistors to the array, the power amplifier effectively becomes larger and operates with a different nominal load impedance. In further examples, Psat can be increased by increasing the power amplifier supply voltage and/or re-biasing the power amplifier's output stage.

Although various examples of Psat controlled are described above and in the embodiments of FIGS. 6A to 6C, and the teachings herein can be used in combination with any Psat control scheme.

FIG. 6A is a schematic diagram of a power amplifier 210 with Psat control according to one embodiment. The power amplifier 210 includes a bipolar transistor 201, a choke inductor 202, and a controllable load impedance 203. The bipolar transistor 201 includes an emitter connected to ground and a base that receives an RF input signal RF_IN for amplification. The bipolar transistor 201 also includes a collector that generates an RF output signal RF_OUT. The collector of the bipolar transistor 201 is connected to the controllable load impedance 203 and receives a power amplifier supply voltage VCC through the choke inductor 202.

In the illustrated embodiment, the control signal CTL from the Wi-Fi system controller adjusts the Psat of the power amplifier 210 by adjusting the load line impedance of the power amplifier 210. However, other implementations of Psat control are possible.

FIG. 6B is a schematic diagram of a power amplifier 220 with Psat control according to another embodiment. The power amplifier 220 includes a bipolar transistor 201, a choke inductor 202, and a supply control circuit 205 controlled by the control signal CTL.

In comparison to the power amplifier 210 of FIG. 6A that controls Psat by adjusting the power amplifier's load impedance, the Psat of the power amplifier 220 of FIG. 6B is controlled by adjusting a voltage level of the power amplifier's supply voltage VCC.

FIG. 6C is a schematic diagram of a power amplifier 230 with Psat control according to another embodiment. The power amplifier 230 includes a bipolar transistor 201, a choke inductor 202, and a bias control circuit 207 controlled by the control signal CTL.

In comparison to the power amplifier 210 of FIG. 6A that controls Psat by adjusting the power amplifier's load impedance, the Psat of the power amplifier 230 of FIG. 6C is controlled by adjusting the power amplifier's bias voltage. For example, a voltage level of a DC bias voltage at the base of the bipolar transistor 201 is adjusted based on the control signal CTL.

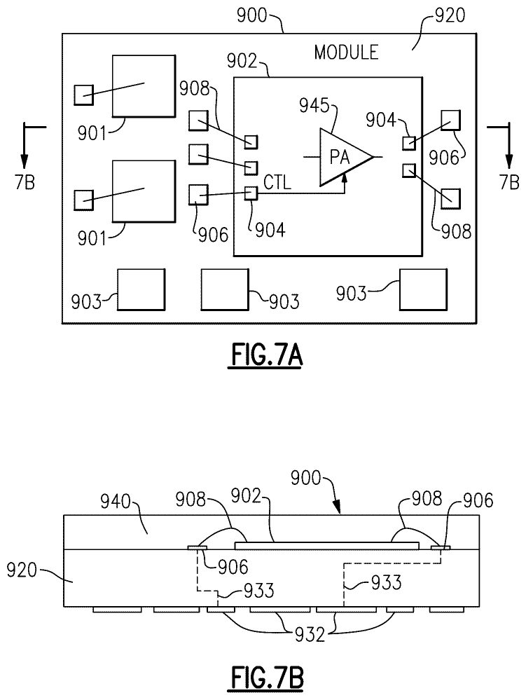

FIG. 7A is a schematic diagram of one embodiment of a packaged module 900. FIG. 7B is a schematic diagram of a cross-section of the packaged module 900 of FIG. 7A taken along the lines 7B-7B.

The packaged module 900 includes radio frequency components 901, a semiconductor die 902, surface mount devices 903, wirebonds 908, a package substrate 920, and an encapsulation structure 940. The package substrate 920 includes pads 906 formed from conductors disposed therein. Additionally, the semiconductor die 902 includes pins or pads 904, and the wirebonds 908 have been used to connect the pads 904 of the die 902 to the pads 906 of the package substrate 920.

The semiconductor die 902 includes a power amplifier 945, which can be implemented in accordance with any of the embodiments herein. As shown in FIG. 7A, the power amplifier 945 receives a control signal CTL over a pin of the semiconductor die 902. Such a control signal can be received from a Wi-Fi system controller, which can be external to the packaged module 900 or implemented on another die of the packaged module 900.

The packaging substrate 920 can be configured to receive a plurality of components such as radio frequency components 901, the semiconductor die 902 and the surface mount devices 903, which can include, for example, surface mount capacitors and/or inductors. In one implementation, the radio frequency components 901 include integrated passive devices (IPDs) and/or another die that includes a Wi-Fi system controller.

As shown in FIG. 7B, the packaged module 900 is shown to include a plurality of contact pads 932 disposed on the side of the packaged module 900 opposite the side used to mount the semiconductor die 902. Configuring the packaged module 900 in this manner can aid in connecting the packaged module 900 to a circuit board, such as a phone board of a mobile device. The example contact pads 932 can be configured to provide radio frequency signals, bias signals, and/or power (for example, a power supply voltage and ground) to the semiconductor die 902 and/or other components. As shown in FIG. 7B, the electrical connections between the contact pads 932 and the semiconductor die 902 can be facilitated by connections 933 through the package substrate 920. The connections 933 can represent electrical paths formed through the package substrate 920, such as connections associated with vias and conductors of a multilayer laminated package substrate.

In some embodiments, the packaged module 900 can also include one or more packaging structures to, for example, provide protection and/or facilitate handling. Such a packaging structure can include overmold or encapsulation structure 940 formed over the packaging substrate 920 and the components and die(s) disposed thereon.

It will be understood that although the packaged module 900 is described in the context of electrical connections based on wirebonds, one or more features of the present disclosure can also be implemented in other packaging configurations, including, for example, flip-chip configurations.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. An access point for a Wi-Fi network, the access point comprising:
a front-end system including a low noise amplifier configured to amplify a receive signal of a first frequency band, and a power amplifier configured to amplify a transmit signal of a second frequency band, the power amplifier further configured to receive a control signal that controls a saturated output power of the power amplifier; and
a system controller including a control circuit configured to use the control signal to operate the power amplifier with a first saturated output power level in a nominal operating mode, and to use the control signal to operate the power amplifier with a second saturated output power level greater than the first saturated output power level in one or more operating modes associated with simultaneous transmission of the transmit signal and reception of the receive signal.

2. The access point of claim 1 wherein the control circuit further detects the one or more operating modes based on comparing a power of the transmit signal to a power threshold.

3. The access point of claim 1 wherein the control circuit further detects the one or more operating modes based on comparing a channel bandwidth of at least one of the transmit signal or the receive signal to a bandwidth threshold.

4. The access point of claim 1 wherein the control circuit further controls a channel selection of at least one of the receive signal or the transmit signal in the one or more operating modes.

5. The access point of claim 1 wherein the control circuit further controls a channel bandwidth of at least one of the receive signal or the transmit signal in the one or more operating modes.

6. The access point of claim 1 wherein the control circuit further controls an output power of the transmit signal in the one or more operating modes.

7. The access point of claim 1 wherein the front-end system further includes an output power limiter connected to an output of the power amplifier.

8. The access point of claim 7 wherein the front-end system further includes an acoustic wave filter downstream from the output of the power amplifier and protected by the output power limiter.

9. The access point of claim 1 wherein the first frequency band is a Wi-Fi 5 GHz band and the second frequency band is a Wi-Fi 6 GHz band.

10. The access point of claim 1 wherein the first frequency band is a Wi-Fi 6 GHZ band and the second frequency band is a Wi-Fi 5 GHz band.

11. The access point of claim 1 wherein the front-end system further includes a controllable load impedance connected to an output of the power amplifier, the control signal operable to control the saturated output power of the power amplifier by adjusting the controllable load impedance.

12. The access point of claim 1 wherein the front-end system further includes a controllable bias circuit configured to bias the power amplifier, the control signal operable to control the saturated output power of the power amplifier by adjusting a bias provided by the controllable bias circuit.

13. The access point of claim 1 wherein the front-end system further includes a controllable supply voltage circuit configured to generate a power amplifier supply voltage for the power amplifier, the control signal operable to control the saturated output power of the power amplifier by adjusting a voltage level of the power amplifier supply voltage provided by the controllable supply voltage circuit.

14. A radio frequency communication system comprising:
a low noise amplifier configured to amplify a receive signal of a first frequency band;
a power amplifier configured to amplify a transmit signal of a second frequency band, and to receive a control signal that controls a saturated output power of the power amplifier; and
a control circuit configured to use the control signal to operate the power amplifier with a first saturated output power level in a nominal operating mode, and to use the control signal to operate the power amplifier with a second saturated output power level greater than the first saturated output power level in one or more operating modes associated with simultaneous transmission of the transmit signal and reception of the receive signal.

15. The radio frequency communication system of claim 14 wherein the control circuit further detects the one or more operating modes based on comparing a power of the transmit signal to a power threshold.

16. The radio frequency communication system of claim 14 wherein the control circuit further detects the one or more operating modes based on comparing a channel bandwidth of at least one of the transmit signal or the receive signal to a bandwidth threshold.

17. A method of radio frequency signal communication, the method comprising:
amplifying a receive signal of a first frequency band using a low noise amplifier;
amplifying a transmit signal of a second frequency band using a power amplifier, the power amplifier receiving a control signal that controls a saturated output power of the power amplifier; and
operating the power amplifier with a first saturated output power level in a nominal operating mode using the control signal; and
operating the power amplifier with a second saturated output power level greater than the first saturated output power level in one or more operating modes associated with simultaneous transmission of the transmit signal and reception of the receive signal using the control signal.

18. The method of claim 17 further comprising detecting the one or more operating modes based on comparing a power of the transmit signal to a power threshold.

19. The method of claim 17 further comprising detecting the one or more operating modes based on comparing a channel bandwidth of at least one of the transmit signal or the receive signal to a bandwidth threshold.

20. The method of claim 17 further comprising controlling an output power of the transmit signal in the one or more operating modes.
